(19) United States
(12) Patent Application Publication
(10) Pub. No.: US 2023/0039400 A1
(43) Pub. Date: Feb. 9, 2023

(54) DISPLAY DEVICE

(71) Applicant: PanelSemi Corporation, New Taipei City (TW)

(72) Inventor: Chin-Tang LI, New Taipei City (TW)

(21) Appl. No.: 17/882,329

(22) Filed: Aug. 5, 2022

(30) Foreign Application Priority Data
Aug. 6, 2021 (TW) 110129143

(51) Int. Cl. H01L 25/16; H01L 33/46; H01L 33/22

(52) U.S. Cl. CPC H01L 25/167; H01L 33/46; H01L 33/22

(57) ABSTRACT

A display device includes a display module and a light-shielding structure. The display module has a substrate, a plurality of photoelectric units and a protective layer. The substrate defines with a first surface and a second surface. The photoelectric units are arranged on the first surface of the substrate, and each photoelectric unit has at least one photoelectric element. The protective layer is arranged on the first surface of the substrate and is filled between the photoelectric elements. The light-shielding structure is arranged on and connected to the protective layer. The light-shielding structure has a light-shielding layer including light-absorption materials and a plurality of windows defined in the light-shielding layer. The windows respectively correspond to the photoelectric units, and the photoelectric units are viewed through the corresponding windows in the direction perpendicular to the first surface of the substrate.

### CROSS REFERENCE TO RELATED APPLICATIONS

This Non-provisional application claims priority under 35 U.S.C. § 119(a) on Patent Application No(s). 110129143 filed in Taiwan, Republic of China on Aug. 6, 2021, the entire contents of which are hereby incorporated by reference.

### BACKGROUND

### Technology Field

The present disclosure relates to a display device and, in particular, to a display device that can improve the display quality degradation caused by ambient light.

### Description of Related Art

The light-emitting diode (LED) is a lighting component made of semiconductor materials. The LED has two electrode terminals. When a voltage is applied between the electrode terminals, the electrons and electric holes can be combined in the semiconductor layers, and the remaining energy can be converted into light so as to output light. Different from the general incandescent light bulbs, LEDs are a cold light source, which has the advantages of low power consumption, long component life, no warm-up time, fast response speed, compact size, vibration durable, and suitable for mass production. Accordingly, the LED can be manufactured into a tiny or matrix module based on the needs in applications, so it can be widely used in lighting equipment, indicators of information, communication or consumer electronic products, backlight modules of display devices, display devices per se. Therefore, LEDs have become one of the essential components in our lives.

Taking the display device as an example, the ambient light source often causes the reflection of ambient images, thereby leading to the display quality degradation, especially in the outdoors. Therefore, it is desired to provide a display device that can solve the issue of the reflection of ambient images caused by the ambient light source, thereby improving the display quality degradation.

### SUMMARY

Embodiments of the present invention are directed to a display device that can improve the display quality degradation caused by the ambient light source.

Embodiments of the present invention provide a display device, which includes a display module and a light-shielding structure. The display module has a substrate, a plurality of photoelectric units and a protective layer. The substrate defines with a first surface and a second surface, and the photoelectric units are arranged on the first surface of the substrate. Each photoelectric unit has at least one photoelectric element. The protective layer is arranged on the first surface of the substrate and is filled between the photoelectric elements. The light-shielding structure is arranged on and connected to the protective layer. The light-shielding structure has a light-shielding layer including light-absorption materials, and a plurality of windows defined in the light-shielding layer. The windows respectively correspond to the photoelectric units, and the photoelectric units are viewed through the corresponding windows in a direction perpendicular to the first surface of the substrate.

In one embodiment, the protective layer is a light-permeable layer.

In one embodiment, the windows respectively correspond to the photoelectric elements, and the photoelectric elements are viewed through the windows in the direction perpendicular to the first surface of the substrate.

In one embodiment, the pitch between adjacent two windows is equal to the pitch between adjacent two photoelectric units.

In one embodiment, the pitch between adjacent two windows is equal to the pitch between adjacent two photoelectric elements.

In one embodiment, the top surface of the protective layer and the top surfaces of the photoelectric elements together define a coplanar surface.

In one embodiment, the protective layer covers the top surfaces of the photoelectric elements.

In one embodiment, the light-shielding layer directly connects the protective layer.

In one embodiment, the light-shielding structure further has a transparent substrate connecting the protective layer, and the light-shielding layer is arranged on the surface of the transparent substrate away from the protective layer.

In one embodiment, the transparent substrate defines a light-emitting surface away from the substrate, and areas of the light-emitting surface corresponding to the windows are roughened.

In one embodiment, each of the windows is an opening defined through the light-shielding layer.

In one embodiment, the light-shielding structure further has a light-permeable element filling a corresponding one of the openings.

In one embodiment, the light-permeable element defines a refractive index matching decreasing away from the protective layer.

In one embodiment, in the direction perpendicular to the first surface of the substrate, the geometric dimension of each window is greater than or equal to the geometric dimension of the corresponding photoelectric unit.

In one embodiment, the light-shielding structure further includes a reflective layer arranged along the light-shielding layer, and the reflective layer is located between the protective layer and the light-shielding layer.

In one embodiment, the contour of the reflective layer is not greater than the contour of the light-shielding layer in the direction perpendicular to the first surface of the substrate.

In one embodiment, the light-shielding layer includes a light absorption material.

In one embodiment, the light-shielding structure further includes a light absorption layer arranged along the light-shielding layer, and the light absorption layer is located at one side of the light-shielding layer away from the protective layer.

In one embodiment, the light-shielding structure further defined plural of window areas corresponding to the windows respectively, and a non-window area representing a remaining area other than the window areas, an ambient-light reflectivity of the non-window area is less than that of at least one of the window areas.

In one embodiment, the protective layer defines a light-emitting surface away from the substrate, and the light-emitting surface is a roughened surface.

As mentioned above, in the display device of this disclosure, the light-shielding structure is arranged on and connected to the protective layer of the display module, and has a light-shielding layer and a plurality of windows defined in the light-shielding layer, the windows respectively correspond to the photoelectric units, and the photoelectric units are viewed through the corresponding windows in a direction perpendicular to the first surface of the substrate. Accordingly, when the ambient image light caused by the ambient light source is reflected to the display device, it can be absorbed by the light-shielding layer. As a result, the display device of this disclosure can improve the display quality degradation caused by the ambient light source.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a display device according to an embodiment of this disclosure; and

FIGS. 2 to 6 are schematic diagrams showing display devices according to different embodiments of this disclosure.

### DETAILED DESCRIPTION OF THE DISCLOSURE

The present disclosure will be apparent from the following detailed description, which proceeds with reference to the accompanying drawings, wherein the same references relate to the same elements.

Each of the display devices in the following embodiments can be an active matrix (AM) display device or a passive matrix (PM) display device, and this disclosure is not limited thereto.

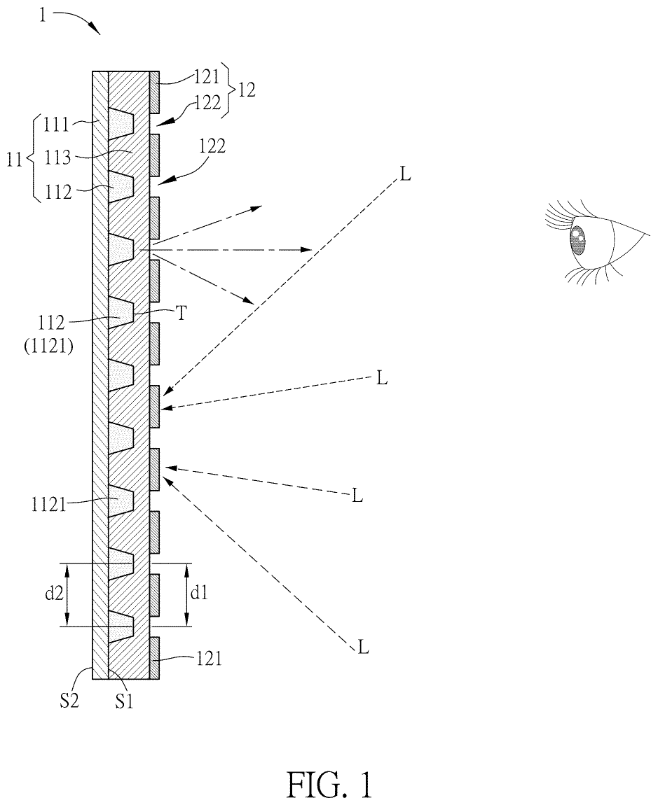

FIG. 1 is a schematic diagram showing a display device 1 according to an embodiment of this disclosure. As shown in FIG. 1, the display device 1 includes a display module 11 and a light-shielding structure 12 connecting to the display module 11. The light-shielding structure 12 is configured to absorb the reflective light L from the ambient light source to the display device 1, so that the viewer can be free from the interference of the ambient light source when viewing the display device 1, thereby improving the display quality degradation caused by the ambient light source.

The display module 11 includes a substrate 111, a plurality of photoelectric units 112, and a protective layer 113.

The substrate 111 is defined with a first surface S1 and a second surface S2 opposite to each other, the photoelectric units 112 are arranged on the first surface S1 of the substrate 111. In this case, the first surface S1 is the surface of the substrate 111 facing the light-shielding structure 12 (as well as the viewer), and the second surface S2 is the surface of the substrate 111 away from the light-shielding structure 12. The photoelectric units 112 are separately distributed one the first surface S1 of the substrate 111 and facing the light-shielding structure 12. In some embodiments, the substrate 111 can be a rigid substrate, a resilient substrate or a composite substrate. For example, if the substrate 111 is a resilient substrate, the display device 1 can be manufactured as a rollable and flexible display device, which is convenient for storage.

Each of the photoelectric units 112 has at least one photoelectric element 1121. In this embodiment, each photoelectric unit 112 has, for example, one photoelectric element 1121. In some embodiments, the photoelectric element 1121 can be a photoelectric chip or a photoelectric package of millimeter or micrometer level. In some embodiments, the photoelectric element 1121 can include, for example but not limited to, a LED chip, a Mini LED chip, a Micro LED chip or a package, or a photoelectric chip or package on or under the level of micrometer or millimeter scale. In this case, the package on or under the level of millimeter scale should include the chip of micrometer level.

In some embodiments, the photoelectric unit 112 may have one photoelectric element 1121, which means that the photoelectric unit 112 or the photoelectric element 1121 can be realized as one single pixel. In some embodiments, the photoelectric unit 112 may have a plurality of photoelectric elements 1121, which means that the multiple photoelectric units 112 or the multiple photoelectric elements 1121 can be realized as a plurality of pixels. In some embodiments, the photoelectric unit 112 or photoelectric element 1121 can include, for example, one or more of red, blue, or green LED, Mini LED, or Micro LED chips, or LED, Mini LED, or Micro LED chips or packages of other colors. When the plurality of photoelectric chips or packages included in the photoelectric unit 112 or the photoelectric element 1121 are red, blue and green LED, Mini LED, or Micro LED chips, the display device 1 can be manufactured as a full-color LED, Mini LED, or micro LED display. In some embodiments, the photoelectric unit 112 or photoelectric element 1121 can include a chip having horizontal electrodes, flip-chip electrodes, or vertical electrodes, which are electrically connected to the circuit layer (not shown) arranged on the substrate 11 by wire bonding or flip-chip bonding. The aforementioned package is not limited to a package with active components or a passive package without active components. The active components can be, for example but not limited to, thin-film transistors (TFTs), silicon ICs, or the like. In some embodiments, the display module 11 may further include one or more driving elements corresponding to the aforementioned photoelectric units 112 or photoelectric elements 1121, so as to drive the photoelectric units 112 or photoelectric elements 1121 to emit light correspondingly. In this case, the above-mentioned driving elements can be arranged on the first surface S1 or/and the second surface S2 of the substrate 111, and this disclosure is not limited thereto. Each of the aforementioned driving elements can include at least one thin-film transistor (TFT), a silicon-semiconductor-based IC, or the like. In some embodiments, in addition to the TFT, the driving element can also include any of other thin-film elements or circuits, such as thin-film resistors, capacitors, or insulating films, and the disclosure is not limited thereto. In practice, the driving elements can be optionally selected depending on the driving method of the photoelectric unit 112 or the photoelectric element 1121.

The protective layer 113 is arranged on the first surface S1 of the substrate 111 and is filled between the photoelectric units 112 (or photoelectric elements 1121). Moreover, the protective layer 113 of this embodiment also covers the top surfaces T of the photoelectric units 112 (photoelectric elements 1121) facing the light-shielding structure 12. Since the protective layer 113 is filled between the photoelectric units 112 and covering the photoelectric units 112, the photoelectric units 112 (photoelectric elements 1121) can be protected from the intrusion of moisture or dusts, which may damage the characteristics thereof. In different embodiments, the protective layer 113 can only be filled between the photoelectric elements 1121 and be leveled with the top surfaces T of the photoelectric units 112 (photoelectric elements 1121). In this embodiment, the protective layer 113 is a light-permeable layer, and it can be a structural layer made of, for example but not limited to, an optical clear adhesive (OCA), an optical clear resin (OCR), or any of other light-permeable materials. For example, the light-permeable material can include inorganic light-permeable materials, light-permeable polymer materials, or light-transmitting composite materials, and this disclosure is not limited thereto.

The light-shielding structure 12 is arranged on and connected to the protective layer 113. The light-shielding structure 12 has a light-shielding layer 121 and a plurality of windows 122 defined in the light-shielding layer 121. In this embodiment, the light-shielding layer 121 is arranged on the protective layer 113 and directly connected to the protective layer 113, and the photoelectric units 12 can be viewed through (seen through) the corresponding windows in the direction perpendicular to the first surface S1 of the substrate 111. In addition, in order to avoid affecting the luminous efficiency of the photoelectric units 112, the geometric dimension of each window 122 must be greater than or equal to the geometric dimension of the corresponding photoelectric unit 112 in the direction perpendicular to the first surface S1 of the substrate 111. In other words, when the viewer views the display device 1 from the side of the light-shielding structure 12 away from the display module 11, the photoelectric unit 112 (or the photoelectric element 1121) can be seen through the window 122, and the light-shielding layer 121 will not affect the light outputted from the photoelectric unit 112 (or the photoelectric element 1121). Even if the light-shielding layer 121 and the photoelectric unit 112 are not completely aligned due to the process factors, once the geometric size of each window 122 is greater than that of the corresponding photoelectric unit 112, the light emitted from the photoelectric unit 112 will not be blocked by the light-shielding layer 121, thereby avoiding to affect the luminous efficiency.

In this embodiment, each window 122 is an opening defined through the light-shielding layer 121 (without filling any material in the openings), and in the direction perpendicular to the first surface S1 of the substrate 111, the light-shielding pattern formed by the light-shielding layer 121 surrounds the peripheries of the photoelectric units 112, so that the light emitted from the photoelectric units 112 can be outputted through the windows 122 respectively. The light-shielding layer 121 per se is made of light-absorption material(s), or at least includes a light absorption material, such as a black or dark ink or photoresist, for absorbing the ambient light reflected from the outside to the display device 1 and thus improving the contrast of the display device 1.

In some embodiments, the pitch between two adjacent windows 122 can be equal to the pitch between two adjacent photoelectric units 112. In some embodiments, the pitch between two adjacent windows 122 can be equal to the pitch between two adjacent photoelectric elements 1121. In this embodiment, the windows 122 respectively correspond to the photoelectric elements 1121 (in the one-on-one manner), the photoelectric elements 1121 are viewed through (seen through) the corresponding windows 122 in the direction perpendicular to the first surface S1, and the pitch d1 between two adjacent windows 122 is equal to the pitch d2 between two adjacent photoelectric elements 1121 (d1=d2). Herein, “the pitch between two adjacent windows 122” is defined as the distance between the middle line of one window 122 and the middle line of the next window 122, and “the pitch between two adjacent photoelectric elements 1121” is defined as the distance between the middle line of one photoelectric element 1121 and the middle line of the next photoelectric element 1121.

In one embodiment, the protective layer 113 defines a light-emitting surface away from the substrate 11, and the light-emitting surface is roughened after the surface treatment process. There are some benefits of the roughened surface, first, it would reduce the possibility of total reflection while the light is travelled from the photoelectric units 112 or the photoelectric element 1121 forward the protective layer 113, and the lighting traveling efficiency of the photoelectric units 112 or the photoelectric element 1121 is consequently increased; second, it would reduce the possibility of reflection from the ambient light source; third, it would clarify the pixel to improve the image quality, while the roughened surface of the protective layer 113, which includes light-absorption materials, improve the light-absorption efficiency.

In some embodiment, the light-shielding structure 12 further defined plural of window areas corresponding to the windows 122 respectively, and a non-window area representing a remaining area other than the widow areas, an ambient-light reflectivity of the non-window area is less than that of at least one of the window areas.

As mentioned above, in the display device 1 of this embodiment, the light-shielding structure 12 is arranged on and connected to the protective layer 113 of the display module 11, and has a light-shielding layer 121 and a plurality of windows 122 defined in the light-shielding layer 121, the windows 122 respectively correspond to the photoelectric units 112, and the photoelectric units 112 are viewed through (seen through) the corresponding windows 122 in the direction perpendicular to the first surface S1 of the substrate 111. Accordingly, when the ambient image light L caused by the ambient light source is reflected to the display device 1, it can be absorbed by the light-shielding layer 121. As a result, the display device 1 of this embodiment can improve the display quality degradation caused by the ambient light source.

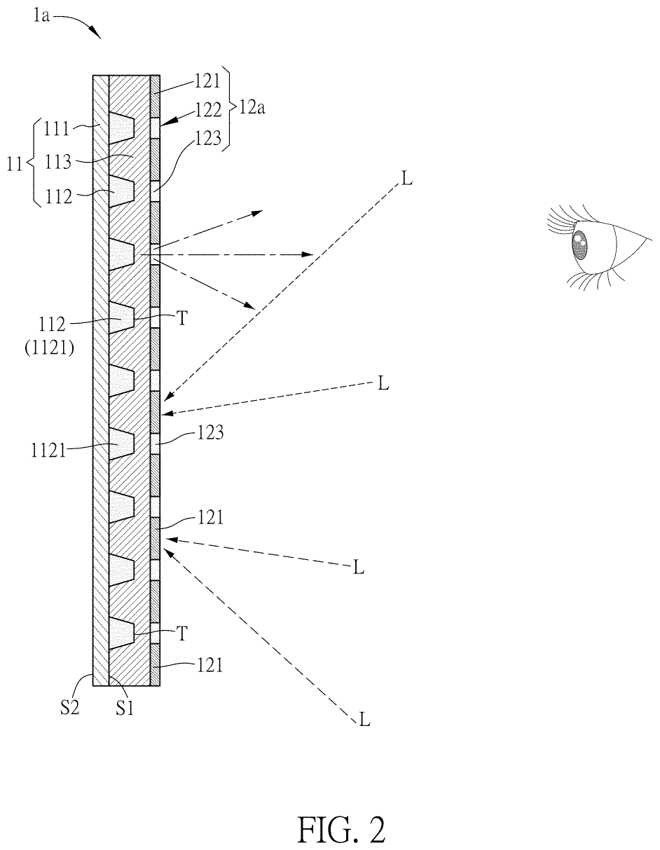

The display devices according to different embodiments of this disclosure will be described hereinafter with reference to FIGS. 2 to 6.

As shown in FIG. 2, the component configurations and connections of the display device 1a of this embodiment are mostly the same as those of the display device 1 of the previous embodiment. Unlike the display device 1 of the previous embodiment, in the display device 1a of this embodiment, each window 122 is an opening defined through the light-shielding layer 121, and the light-shielding structure 12 further includes a light-permeable element 123, which fills the openings. The material of the light-permeable element 123 can be, for example but not limited to, an optical clear adhesive (OCA), an optical clear resin (OCR), or any of other light-permeable materials. For example, the light-permeable material can include inorganic light-permeable materials, light-permeable polymer materials, or light-transmitting composite materials, and this disclosure is not limited thereto. Moreover, it is desired, for decreasing the risks of possible scratching and damaging to the light-shielding structure 12 caused by external stresses, to provide an additional cover layer (not shown) at one side of the light-shielding structure 12 close to the viewer, and this disclosure is not limited. In some cases, the light-permeable element 123 defines a refractive index matching decreasing away from the protective layer 113, which means the refractive index matching of the light-permeable element 123 decreases from a side adjacent to the protective layer 113 to an opposite side adjacent to the air therearound, to improve the image quality.

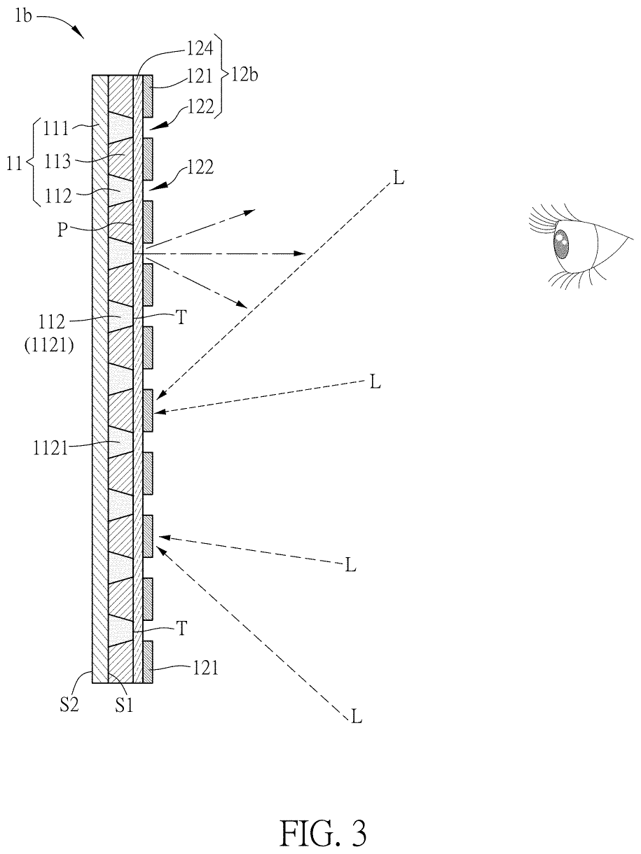

As shown in FIG. 3, the component configurations and connections of the display device 1b of this embodiment are mostly the same as those of the display device 1 of the previous embodiment. Unlike the display device 1 of the previous embodiment, in the display device 1b of this embodiment, the protective layer 113 is only filled between and around the photoelectric units 112 (the photoelectric elements 1121) without covering the top surfaces T of the photoelectric units 112 (the photoelectric elements 1121). In this embodiment, the top surface of the protective layer 113 and the top surfaces T of the photoelectric units 112 (the photoelectric elements 1121) are leveled and together define a coplanar surface P. Furthermore, the light-shielding structure 12b of this embodiment further includes a transparent substrate 124 connecting the protective layer 113, and the light-shielding layer 121 is arranged on a surface of the transparent substrate 124 away from the protective layer 113. In this case, since the protective layer 113 is leveled with the top surfaces T of the photoelectric units 112 (the photoelectric elements 1121), the transparent substrate 124 can connect the coplanar surface P defined by the top surface of the protective layer 113 and the top surfaces T of the photoelectric units 112 (the photoelectric elements 1121). In this case, the openings of the light-shielding structure 12 would be further through the transparent substrate 124 for communicating therethrough, or the transparent substrate 124 would close the openings of light-shielding layer 121. In the case of closure of the openings of light-shielding layer 121, the transparent substrate 124 defines a light-emitting surface away from the substrate 11, and areas of the light-emitting surface corresponding to the windows 122 are roughened, so as to improve the image quality.

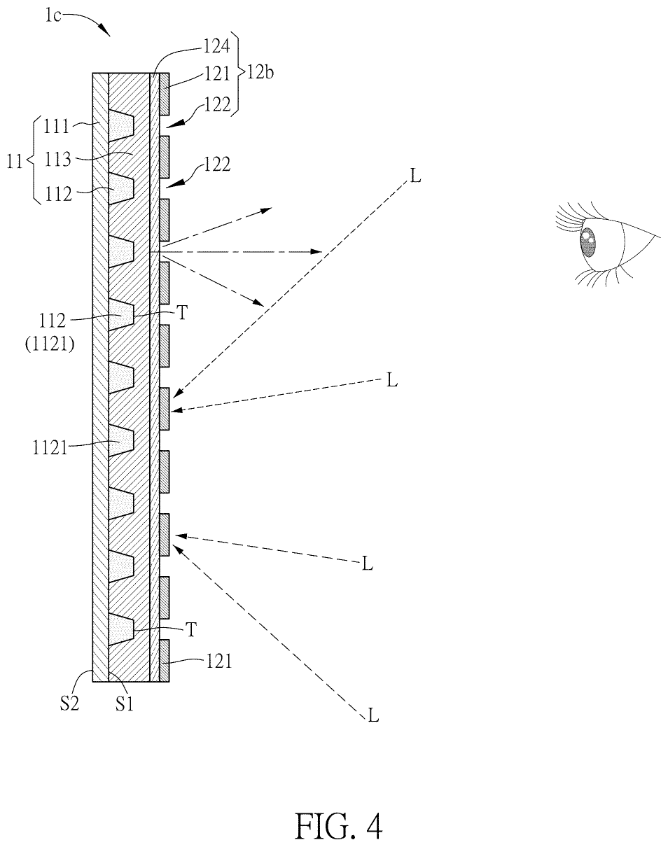

As shown in FIG. 4, the component configurations and connections of the display device 1c of this embodiment are mostly the same as those of the display device 1 of the previous embodiment. Unlike the display device 1 of the previous embodiment, in the display device 1c of this embodiment, the light-shielding structure 12c further includes a transparent substrate 124, which connects the protective layer 113, and the light-shielding layer 121 is arranged on a surface of the transparent substrate 124 away from the protective layer 113.

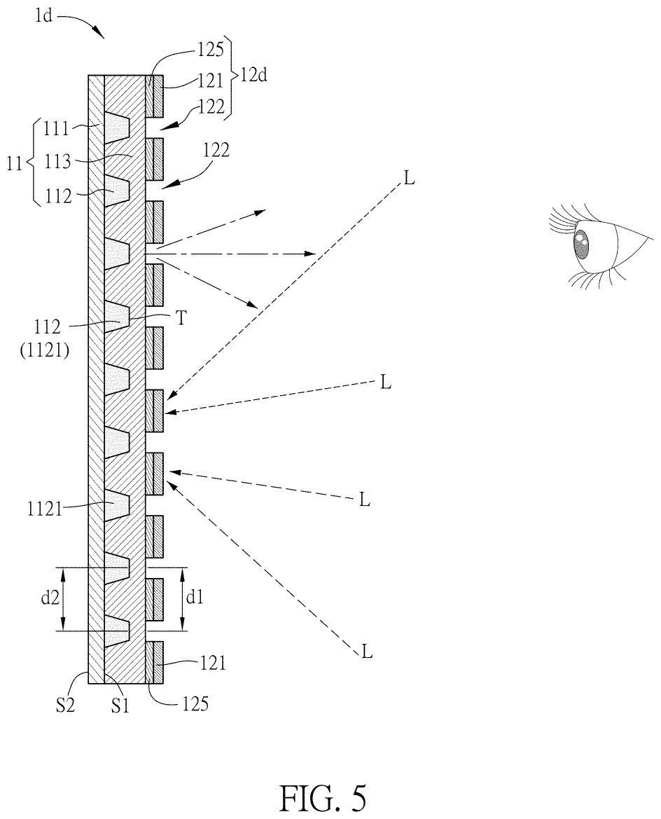

As shown in FIG. 5, the component configurations and connections of the display device 1d of this embodiment are mostly the same as those of the display device 1 of the previous embodiment. Unlike the display device 1 of the previous embodiment, in the display device 1d of this embodiment, the light-shielding structure 12d further includes a reflective layer 125 arranged along the light-shielding layer 121, and the reflective layer 125 is located between the protective layer 113 and the light-shielding layer 121. Based on this design, the light emitted from the photoelectric unit 112 toward the light-shielding layer 121 can be reflected by the reflective layer 125, thereby improving the light utilization rate of the photoelectric units 112. The contour of the reflective layer 125 can be not greater than that of the light-shielding layer 121 in the direction perpendicular to the first surface of the substrate. In other words, in the direction parallel to the first surface S1 of the substrate 111, the present embodiment does not limit the width of the reflective layer 125 to be the same as that of the light-shielding layer 121. For example, the width of the reflecting layer 125 can be equal to or less than the width of the light-shielding layer 121. In this embodiment, the contour of the reflective layer 125 is equal to the contour of the light-shielding layer 121 as an example.

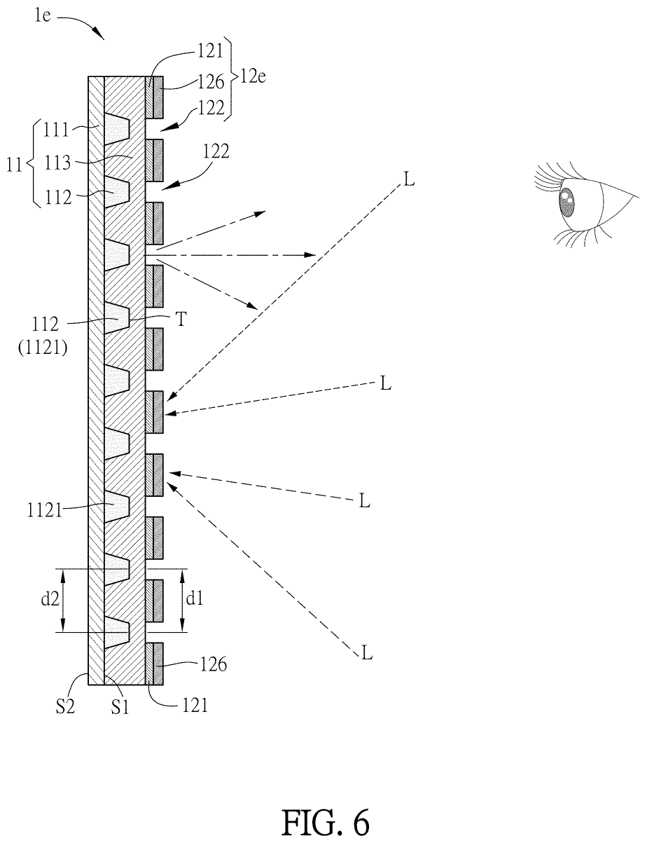

As shown in FIG. 6, the component configurations and connections of the display device 1e of this embodiment are mostly the same as those of the display device 1 of the previous embodiment. Unlike the display device 1 of the previous embodiment, in the display device 1e of this embodiment, the light-shielding layer 12e includes a light absorption layer 126 arranged along the light-shielding layer 121, and the light absorption layer 126 is located at one side of the light-shielding layer 121 away from the protective layer 113. In this embodiment, the light absorption layer 126 is connected with one side of the light-shielding layer 121 away from the protective layer 113. In this case, the light-shielding layer 121 can include a light absorption material, and the light absorption material of the light absorption layer 126 can be the same as or different from that of the light-shielding layer 121. This disclosure is not limited thereto.

To be noted, the light-permeable element 123 of the display device 1a as shown in FIG. 2 can be applied to any of the display devices 1b˜1e as shown in FIGS. 3 to 6.

To be understood, in the conventional art, the light-shielding structure (light-shielding layer) is directly formed inside the display module (for example, the black matrix (BM) is arranged on the substrate and is located at the periphery of the photoelectric unit), but it may have non-uniform refractive indexes due to the non-uniform material distribution after the molding process, which will cause the reflection of external light source. To solve this problem of the conventional art, the present disclosure arranges the light-shielding structure (light-shielding layer) outside the display module, which can effectively reduce the interference of the displayed image caused by the reflection of external light source, thereby avoiding to induce the problem of display quality degradation.

In summary, in the display device of this disclosure, the light-shielding structure is arranged on and connected to the protective layer of the display module, and has a light-shielding layer and a plurality of windows defined in the light-shielding layer, the windows respectively correspond to the photoelectric units, and the photoelectric units are viewed through the corresponding windows in a direction perpendicular to the first surface of the substrate. Accordingly, when the ambient image light caused by the ambient light source is reflected to the display device, it can be absorbed by the light-shielding layer. As a result, the display device of this disclosure can improve the display quality degradation caused by the ambient light source.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A display device, comprising:
a display module having a substrate, a plurality of photoelectric units and a protective layer, wherein the substrate defines with a first surface and a second surface opposite to each other, the photoelectric units are arranged on the first surface of the substrate, each of the photoelectric units has at least one photoelectric element, and the protective layer is arranged on the first surface of the substrate and is filled between the photoelectric elements; and
a light-shielding structure arranged on and connected to the protective layer, wherein the light-shielding structure has a light-shielding layer including light-absorption materials, and a plurality of windows defined in the light-shielding layer; the windows respectively correspond to the photoelectric units, and the photoelectric units are viewed through the corresponding windows in a direction perpendicular to the first surface of the substrate.

2. The display device of claim 1, wherein the protective layer is a light-permeable layer.

3. The display device of claim 1, wherein the windows respectively correspond to the photoelectric elements, and the photoelectric elements are viewed through the windows in the direction perpendicular to the first surface of the substrate.

4. The display device of claim 1, wherein a pitch between adjacent two of the windows is equal to a pitch between adjacent two of the photoelectric units.

5. The display device of claim 1, wherein a pitch between adjacent two of the windows is equal to a pitch between adjacent two of the photoelectric elements.

6. The display device of claim 1, wherein a top surface of the protective layer and top surfaces of the photoelectric elements together define a coplanar surface.

7. The display device of claim 1, wherein the protective layer covers top surfaces of the photoelectric elements.

8. The display device of claim 1, wherein the light-shielding layer directly connects the protective layer.

9. The display device of claim 1, wherein the light-shielding structure further has a transparent substrate connecting the protective layer, and the light-shielding layer is arranged on a surface of the transparent substrate away from the protective layer.

10. The display device of claim 1, wherein each of the windows is an opening defined through the light-shielding layer.

11. The display device of claim 10, wherein the light-shielding structure further has a light-permeable element filling a corresponding one of the openings.

12. The display device of claim 11, wherein the light-permeable element defines a refractive index matching decreasing away from the protective layer.

13. The display device of claim 1, wherein, in the direction perpendicular to the first surface of the substrate, a geometric dimension of each of the windows is greater than or equal to a geometric dimension of corresponding one of the photoelectric units.

14. The display device of claim 1, wherein the light-shielding structure further includes a reflective layer arranged along the light-shielding layer, and the reflective layer is located between the protective layer and the light-shielding layer.

15. The display device of claim 14, wherein a contour of the reflective layer is not greater than a contour of the light-shielding layer.

16. The display device of claim 1, wherein the light-shielding layer comprises a light absorption material.

17. The display device of claim 1, wherein the light-shielding structure further comprises a light absorption layer arranged along the light-shielding layer, and the light absorption layer is located at one side of the light-shielding layer away from the protective layer.

18. The display device of claim 1, wherein the light-shielding structure further defined plural of window areas corresponding to the widows respectively, and a non-window area representing a remaining area other than the widow areas, an ambient-light reflectivity of the non-window area is less than that of at least one of the window areas.

19. The display device of claim 1, wherein the protective layer defines a light-emitting surface away from the substrate, and the light-emitting surface is a roughened surface.
